(19) United States
(12) Patent Application Publication
(10) Pub. No.: US 2025/0212378 A1
(43) Pub. Date: Jun. 26, 2025

(54) Semiconductor Structures with Backside Buried Contact

(71) Applicant: Taiwan Semiconductor Manufacturing Company, Ltd., Hsin-Chu (TW)

(72) Inventors: Ping-Wei WANG, Hsinchu (TW); Jui-Lin CHEN, Taipei City (TW)

(21) Appl. No.: 18/405,311

(22) Filed: Jan. 5, 2024

Related U.S. Application Data
(60) Provisional application No. 63/613,398, filed on Dec. 21, 2023.

(51) Int. Cl. H10B 10/00; H01L 23/528; H01L 27/088; H01L 29/06; H01L 29/08; H01L 29/423; H01L 29/66; H01L 29/775; H01L 29/786

(52) U.S. Cl. CPC H10B 10/12; H01L 23/5286; H10D 30/014; H10D 30/43; H10D 30/6735; H10D 30/6757; H10D 62/121; H10D 62/151; H10D 64/017; H10D 84/83

(57) ABSTRACT

A semiconductor structure includes an active region including a stack of channel layers, a metal gate structure disposed over the stack of channel layers, a source/drain feature disposed over a source/drain region of the active region and adjacent to the stack of channel layers, and a backside via penetrating from a back side of the active region and extending to contact a channel layer of the stack of channel layers. The backside via is electrically connected to the source/drain feature through the channel layer of the stack of channel layers and contacts the metal gate structure.

This is a non-provisional application of and claims the benefit of U.S. Provisional Patent Application Ser. No. 63/613,398 filed Dec. 21, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In deep sub-micron integrated circuit technology, static random-access memory (SRAM) device has become a popular storage unit of high-speed communication, image processing, and system-on-chip (SOC) products. As silicon technology continues to scale from one generation to the next, conventional SRAM devices and/or the fabrication thereof may encounter limitations. For example, aggressive scaling down of IC dimensions has resulted in densely spaced source/drain features and gate structures, and densely spaced source/drain contacts and gate vias formed thereover. In some SRAM devices, multilayer interconnect structure providing metal lines for interconnecting power lines and signal lines in and between memory cells of the SRAM devices are formed over source/drain contacts and gate vias of the transistors of the memory cells. With ever-decreasing device sizes and densely spaced transistors, some metal lines (e.g., metal lines for power routings) are formed to have reduced dimensions, which may lead to increased parasitic resistance, increased parasitic capacitance, high process risk, and/or poor connection, which may degrade the speed of the memory devices. All those issues present performance, yield, and cost challenges. Therefore, while existing SRAM devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2 illustrates a fragmentary layout of an exemplary workpiece in accordance with some embodiments of the present disclosure.

FIGS. 3A, 4A, 5A, 6A, and 7A illustrate fragmentary cross-sectional views of the exemplary workpiece during a fabrication process according to the method of FIG. 1 along line A-A of FIG. 2, according to one or more aspects of the present disclosure.

FIGS. 3B, 4B, 5B, 6B, and 7B illustrate fragmentary cross-sectional views of the exemplary workpiece during a fabrication process according to the method of FIG. 1 along line B-B of FIG. 2, according to one or more aspects of the present disclosure.

FIG. 8 illustrates a circuit schematic of a static random-access memory (SRAM) cell, in accordance with some embodiments of the present disclosure.

FIGS. 9A, 10A, 11A, 12A, 13A, and 14A illustrate fragmentary cross-sectional views of alternative workpieces along line A-A of FIG. 2, according to one or more aspects of the present disclosure.

FIGS. 9B, 10B, 11B, 12B, 13B, and 14B illustrate fragmentary cross-sectional views of the alternative workpieces along line B-B of FIG. 2, according to one or more aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Static random-access memory (SRAM) is an electronic data storage device implemented on a semiconductor-based integrated circuit and generally has much faster access times than other types of data storage technologies. SRAM is popular in high-speed communication, image processing and system-on-chip (SOC) applications. A bit can be read from or written into an SRAM cell within a few nanoseconds. An SRAM cell include transistors with metal interconnect structures above the transistors. The metal interconnect structures include metal lines for interconnecting transistor gates and source/drain regions, such as signal lines for routing bit line and word line signals to the cell components, as well as power rails (such as metal lines for power voltage and electrical ground) for providing power to the cell components. Contacts and respective contact vias electrically connect the cell components to the signal lines and the power rails. For example, some of the source/drain regions in an SRAM cell are coupled to a power voltage VDD (also referred to as VCC) and/or an electrical ground VSS through source/drain contacts, source/drain contact vias, and respective metal lines in the power rails. Source/drain region(s) may refer to a source or a drain, individually or collectively dependent upon the context.

Conventionally, SRAM devices are built in a stacked-up fashion, having transistors at the lowest level and interconnect structures (contacts, vias, and metal lines) on top of the transistors to provide connectivity to the transistors. For example, interconnect structures may include a frontside butted contact that electrically connects the source/drain feature to a gate of the pull-down transistor and the pull-up transistor, which takes up space above the transistors. Power rails are also above the transistors and may be part of the interconnect structures. With the increasing downscaling of SRAM devices, so do the power rails. As available layout area becomes limited and metal lines in the power rails are generally formed to have reduced dimensions. This inevitably leads to increased voltage drop across the power rails, as well as increased power consumption, which has become a key issue in further boosting performance of SRAM devices. Therefore, although existing approaches in semiconductor fabrication have been generally adequate for their intended purposes, they have not been entirely satisfactory in all respects in the context of SRAM devices.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed.

The present disclosure provides various embodiments of a semiconductor device. Particularly, the present disclosure provides a semiconductor device with a backside buried contact. The semiconductor device includes a stack of channel layers, a gate stack over the stack of channel layers, and a source/drain feature contacting the stack of channel layers. The backside buried contact extends from a back side of the semiconductor device to contact a channel layer of the stack of channel layers. The backside buried contact extends through and directly contacts a portion of the gate stack. Thus, the backside buried contact electrically connects the gate stack and the source/drain feature. In some embodiments, the backside buried contact extends through multiple channel layers of the stack of channel layers. Because the backside buried contact is below the stack of channel layers, frontside via density of the semiconductor device may be reduced, providing increased space for frontside conductive features, such as metal lines and vias. The semiconductor device may include a static-random-access memory (SRAM) cell. The stack of channel layers may be at an end portion of an active region. The backside buried contact may be directly below an intersection of the end portion of the active region and the gate stack.

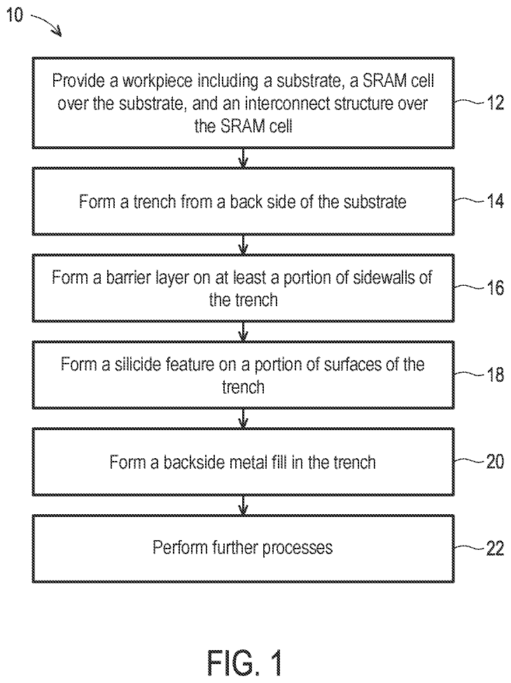

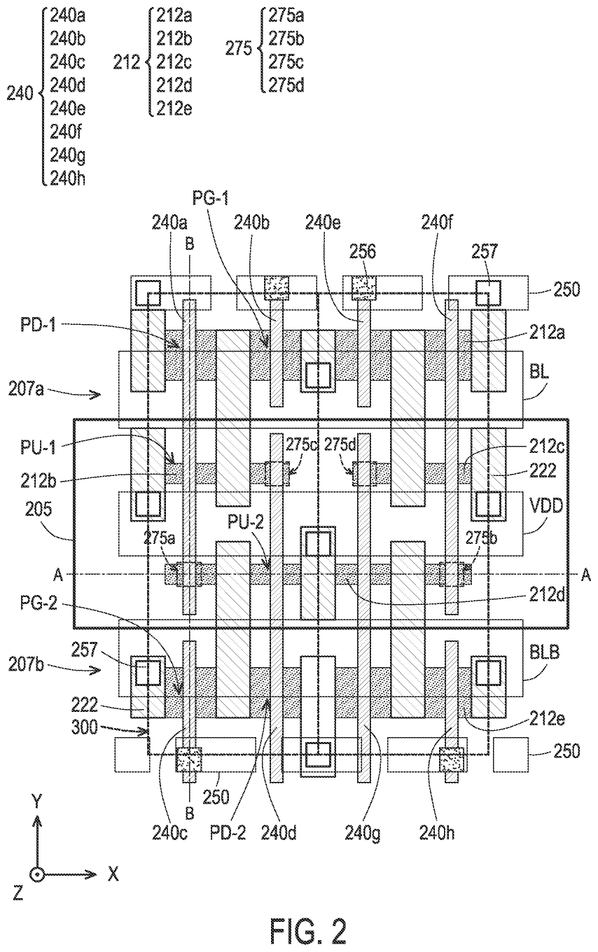

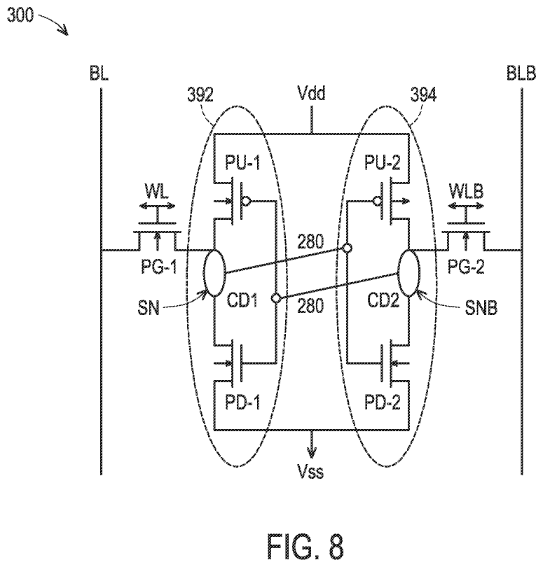

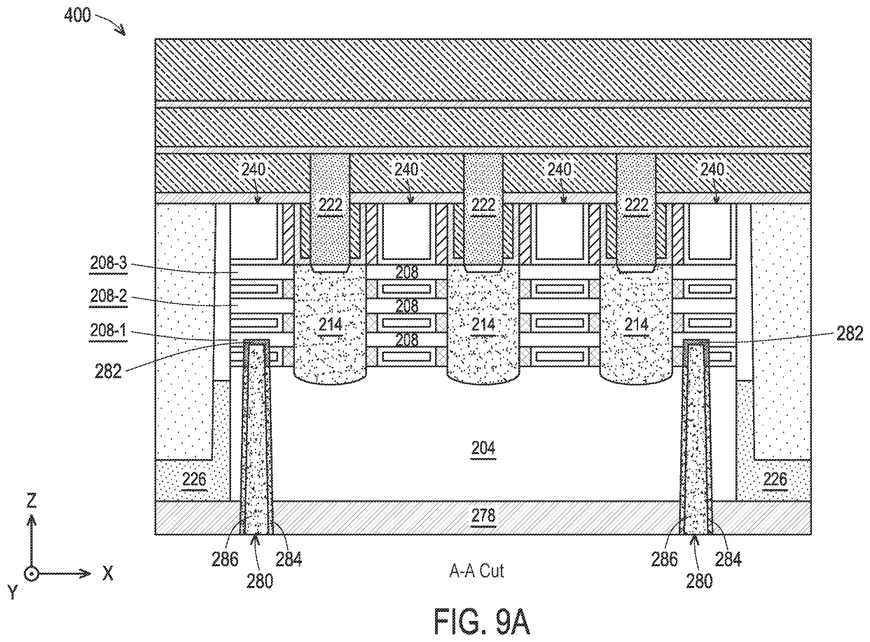

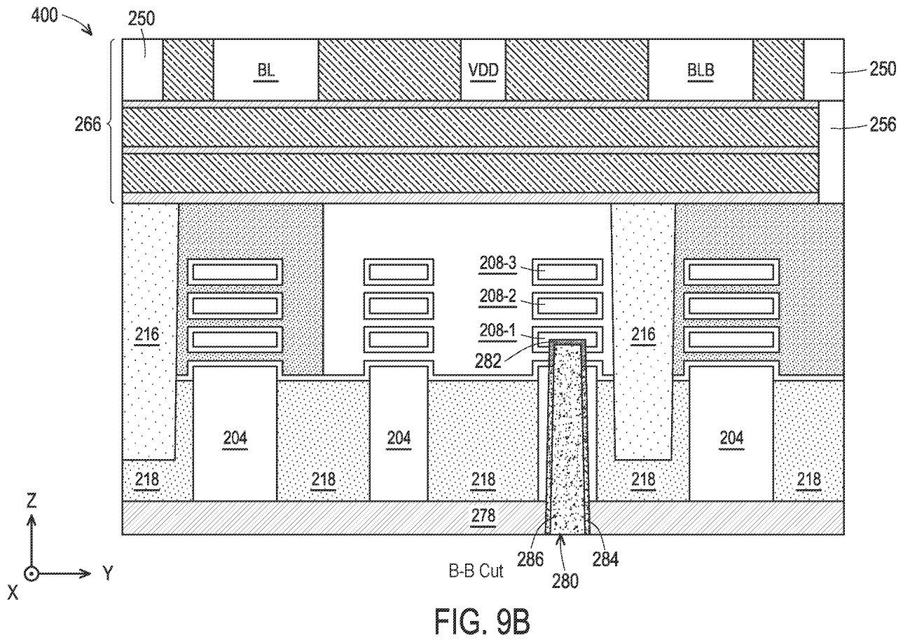

The various aspects of the present disclosure will now be described in more detail with reference to the figures. In that regard, FIG. 1 is a flowchart illustrating a method 10 of forming a semiconductor device from a workpiece according to embodiments of the present disclosure. Method 10 is merely an example and is not intended to limit the present disclosure to what is explicitly illustrated in method 10. Additional steps can be provided before, during, and after the method 10, and some steps described can be replaced, eliminated, or moved around for additional embodiments of the method. Not all steps are described herein in detail for reasons of simplicity. Method 10 is described below in conjunction with FIGS. 2-7B, which are fragmentary layout or cross-sectional views of a workpiece 200 at different stages of fabrication according to embodiments of the method 10 in FIG. 1. Because the workpiece 200 will be fabricated into a semiconductor structure or a semiconductor device, the workpiece 200 may be referred to herein as a semiconductor structure 200 or a semiconductor device 200 as the context requires. FIG. 8 is a circuit schematic of an SRAM cell 300, which is equivalent to a portion of the workpiece 200. FIGS. 9A-14B are fragmentary cross-sectional views of alternative workpieces 400, 500, 600, 700, 800, and 900, respectively. For avoidance, the X, Y and Z directions in FIGS. 2-7B and 9A-14B are perpendicular to one another. Additionally, throughout the disclosure, like reference numerals may denote like features.

In some embodiments, the semiconductor device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

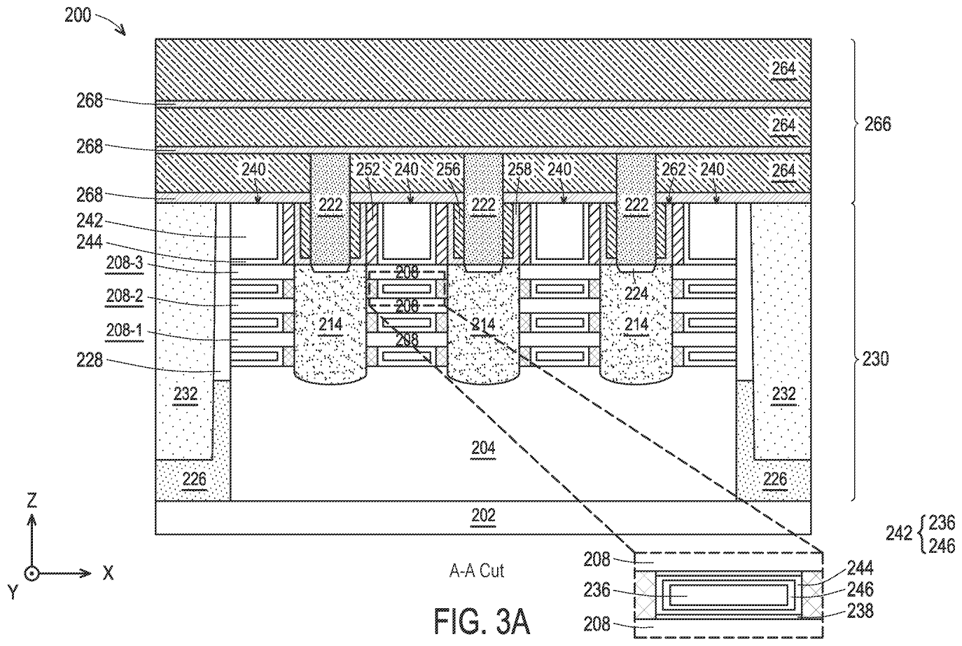

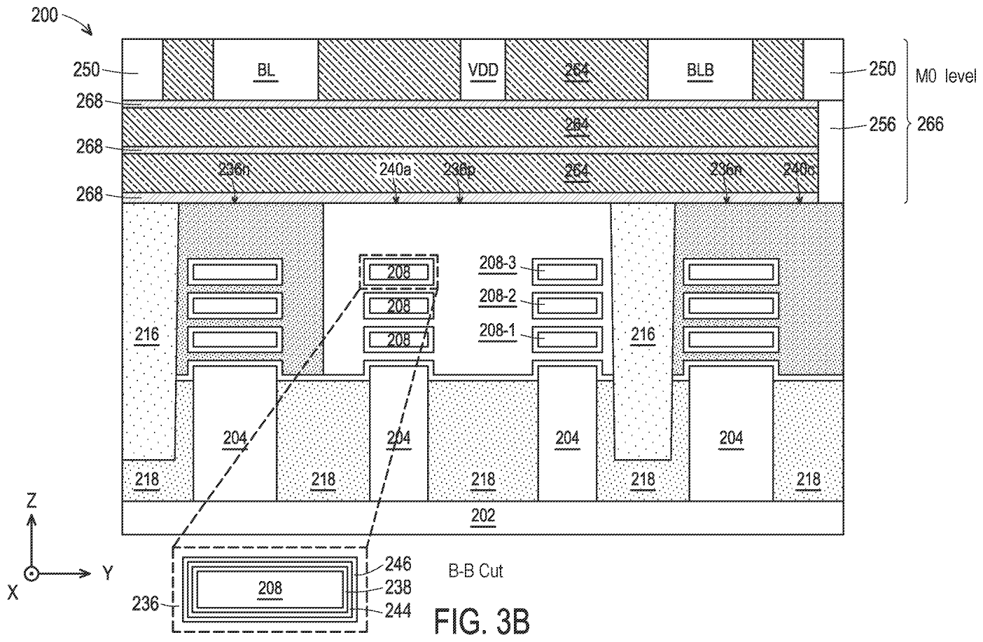

Referring to FIGS. 1 and 2-3B, method 10 includes a block 12 where the workpiece 200 is provided. FIG. 2 illustrates a fragmentary layout of the workpiece 200 according to aspects of the present disclosure. FIGS. 3A and 3B illustrate fragmentary cross-sectional views of the workpiece 200 at block 12 along line A-A and line B-B of FIG. 2, respectively.

Referring to FIG. 2, the workpiece 200 includes multiple active regions 212 oriented lengthwise along the X-direction and multiple gate stacks 240 oriented lengthwise along the Y-direction. An active region for a transistor refers to the area where a source region, a drain region, and a channel region under a gate structure of the transistor are formed. An active region is also referred to as an “oxide-definition (OD) region” in the context. As depicted in FIG. 2, the active regions 212 include active regions 212a, 212b, 212c, 212d, and 212e, which may be individually or collectively referred to as active region(s) 212 dependent upon the context. In some embodiments, the active regions 212a and 212e are n-type active regions and are disposed over P-well regions 207a and 207b, respectively. In embodiments, the active regions 212b, 212c, and 212d are p-type active regions and are disposed over an N-well region 205. In embodiments, the active regions 212 are fin-like structures and are also referred to as fin-like structures 212. The gate stacks 240 includes gate stacks 240a, 240b, 240c, 240d, 240e, 240f, 240g, 240h, which may be individually or collectively referred to as gate stack(s) 240 dependent upon the context. The gate stack 240a is disposed over the active regions 212a, 212b, and 212d; the gate stack 240b is disposed over the active region 212a; the gate stack 240c is disposed over the active region 212e; and the gate stack 240d is disposed over the active regions 212b, 212d, and 212e. At intersections of the active regions 212 and the gate stacks 240, transistors (e.g., pull-up transistors PU-1 and PU-2, pull-down transistors PD-1 and PD-2, pass-gate transistors PG-1 and PG-2) are formed. In the context of a GAA transistor formed at in an intersection of an active region 212 and a gate stack 240, the active region 212 includes elongated nanostructures (also referred to as channel members or channel layers) vertically stacked in channel regions defined in the active region 212 and above a semiconductor base 204 (to be described below) of the active region 212. The semiconductor base 204 protrudes upwardly out of a substrate 202 (to be described below). In some embodiments, portions of the active regions 212 that are not covered by the gate stacks 240 serve as the source/drain regions. Source/drain features (to be described below) are formed in source/drain regions defined in the active region 212 and over the semiconductor base 204. The source/drain features abut two opposing ends of the nanostructures.

Referring to FIGS. 3A-3B, the workpiece 200 includes the substrate 202 at its back side. In some embodiments, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In an alternative embodiment, substrate 202 is a semiconductor-on-insulator substrate, such as a silicon-on-insulator (SOI) substrate, a silicon germanium-on-insulator (SGOI) substrate, or a germanium-on-insulator (GOI) substrate. In embodiments, the substrate 202 may include a conductive layer, a semiconductor layer, a dielectric layer, other layers, or combinations thereof. Various doped regions may be formed in or on the substrate 202. The doped regions may be doped with n-type dopants, such as phosphorus or arsenic, and/or p-type dopants, such as boron, depending on design requirements. The doped regions may be formed directly on the substrate 202, in a p-well structure, in an n-well structure, in a dual-well structure, or using a raised structure. Doped regions may be formed by implantation of dopant atoms, in-situ doped epitaxial growth, and/or other suitable techniques.

In embodiments, the workpiece 200 includes the active regions 212 over the substrate 202. Each of the active regions 212 includes a semiconductor base 204 protruding from the substrate 202 and stacks of nanostructures 208 vertically stacked and suspended over the semiconductor base 204. In embodiments, the semiconductor bases 204 include silicon, silicon germanium, germanium, or other suitable semiconductor, and may be doped with n-type or p-type dopants. The active regions 212 may be patterned by any suitable method. For example, the active regions 212 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used as a masking element for patterning the active regions 212. For example, the masking element may be used for etching recesses into semiconductor layers over or in the substrate 202, leaving the active regions 212 on the substrate 202. The etching process may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Numerous other embodiments of methods to form the active regions 212 may be suitable.

The nanostructures 208 in a stack connect two source/drain features 214 and function as channel layers of the GAA transistors. Thus, the nanostructures 208 may also be referred to as the channel layers 208. The nanostructures 208 may include a semiconductor material suitable for transistor channels, such as silicon, silicon germanium, or other semiconductor material(s). The nanostructures 208 may be in the shape of rods, bars, sheets, or other shapes in various embodiments. In an embodiment, the nanostructures 208 are initially part of a stack of semiconductor layers that include the nanostructures 208 and other sacrificial semiconductor layers alternately stacked layer-by-layer. The sacrificial semiconductor layers and the nanostructures 208 include different material compositions (such as different semiconductor materials, different constituent atomic percentages, and/or different constituent weight percentages) to achieve etching selectivity. During a gate replacement process to form the gate stacks 240, the sacrificial semiconductor layers are selectively removed, leaving the nanostructures 208 suspended over the semiconductor base 204. It is noted that three (3) nanostructures 208 are vertically stacked in the illustrated embodiment, which is for illustrative purposes only and not intended to be limiting beyond what is specifically recited in the claims. It can be appreciated that any number of nanostructures can be formed, depending on device performance needs. In some embodiments, the number of nanostructures 208 vertically stacked is between (including) 2 and 10.

In the present embodiments, the workpiece 200 also includes an isolation feature 218 (shown in FIG. 3B) formed around each active region 212 to isolate two adjacent active regions 212. The isolation feature 218 may also be referred to as a shallow trench isolation (STI) feature and may include silicon oxide, silicon oxynitride, fluorine-doped silicate glass (FSG), a low-k dielectric, combinations thereof, and/or other suitable materials.

In some embodiments, the workpiece 200 includes fin-cut structures 230 over the substrate 202 (as in FIG. 3A). The fin-cut structures 230 separate one active region 212 from another active region 212 that is aligned with the one active region 212 along the X direction. In the depicted embodiment, the fin-cut structures 230 contact the channel layers 208 and the gate stacks 240. In embodiments, each of the fin-cut structures 230 include a first dielectric layer 226 embedded in the semiconductor base 204, a second dielectric layer 228 disposed over the first dielectric layer 226, and a third dielectric layer 232 extending into the first dielectric layer 226 and the second dielectric layer 228. The fin-cut structures 230 may be formed using various different processes. In an example process, fin cut trenches along the Y direction are formed to divide one or more active regions 212 into segments. An isolation dielectric material, such as silicon oxide, silicon nitride, silicon oxynitride, is deposited over the workpiece 200, including into the recesses and trenches among active regions 212. The deposited isolation dielectric material is then planarized, such as by a chemical mechanical polishing (CMP), and then etched back to form the first dielectric layer 226. In some instances, the first dielectric layer 226 may be a shallow trench isolation (STI) feature and may be referred to as such. In various examples, the second dielectric layer 228 may be formed over the first dielectric layer 226 similar to the forming of the first dielectric layer 226 (e.g., depositing an isolation dielectric material and performing a CMP process). In some embodiments, a secondary trench is formed in the first dielectric layer 226 and the second dielectric layer 228. The third dielectric layer 232 is then formed in the secondary trench similarly to the forming of the second dielectric layer 228. The second dielectric layer 228 may include silicon oxide, silicon nitride, silicon oxynitride, silicon oxycarbonitride, silicon carbonitride, or silicon carbide. The third dielectric layer 232 may include an isolation material, for example, silicon oxide, TEOS formed oxide, PSG, BPSG, low-k dielectric material, other suitable dielectric material, or combinations thereof. Exemplary low-k dielectric materials include FSG, carbon doped silicon oxide, Xerogel, Aerogel, amorphous fluorinated carbon, Parylene, BCB, polyimide, other low-k dielectric material, or combinations thereof. In some embodiments, the second dielectric layer 228 and the third dielectric layer 232 include multiple layers. In various examples, the fin-cut structure 230 further include an etch stop layer (ESL, not depicted), which may be disposed in the secondary trench conformally before depositing the third dielectric layer 232. The ESL may include silicon nitride.

In some embodiments, the workpiece 200 includes the source/drain features 214 formed in and/or over source/drain regions of the active regions 212, each being disposed adjacent to the gate stacks 240. The source/drain feature(s) 214 may refer to a source or a drain, individually or collectively dependent upon the context. The source/drain features 214 may be formed by any suitable techniques, such as etching processes followed by one or more epitaxial growth processes. In one example, one or more etching processes are performed to remove portions of the active regions 212 to form recesses (not shown) in the source/drain regions. A cleaning process may be performed to clean the recesses with a hydrofluoric acid (HF) solution or other suitable solution. Subsequently, one or more epitaxial growth processes are performed to grow the source/drain features 214 in the recesses. Each of the source/drain features 214 may be suitable for forming a p-type device or alternatively, an n-type device. The p-type source/drain features of p-type transistors (e.g., the pull-up transistors PU-1 and PU-2) may include one or more epitaxial layers of silicon germanium (epi SiGe) doped with a p-type dopant such as boron, germanium, indium, and/or other p-type dopants. The n-type source/drain features of n-type transistors (e.g., the pass-gate transistors PG-1, PG-2, the pull-down transistors PD-1, PD-2) may include one or more epitaxial layers of silicon (epi Si) or silicon carbon (epi SiC) doped with an n-type dopant such as arsenic, phosphorus, and/or other n-type dopant.

In some embodiments, the workpiece 200 further includes inner spacers 254 disposed between the S/D features 214 and the adjacent gate stacks 240. In some embodiments, the inner spacers 254 include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 254 include a low-k dielectric material, such as those described herein. The inner spacers 254 may be formed by deposition and etching processes. For example, after S/D trenches are etched and before the S/D features 214 are epitaxially grown from the S/D trenches, an etch process may be used to recess the sacrificial layers between the adjacent channel layers 208 to form gaps vertically between the adjacent channel layers 208. Then, one or more dielectric materials are deposited (using CVD or ALD for example) to fill the gaps. Another etching process is performed to remove the dielectric materials outside the gaps, thereby forming the inner spacers 254.

In some embodiments, the workpiece includes gate stacks 240 between two source/drain features 214, disposed over and wrapping around each of the channel layers 208. Referring to FIGS. 3A and 3B, the gate stacks 240 may include an interfacial layer 238 formed on surfaces of the channel layers 208 interfacing the gate stacks 240, a high-k dielectric layer 244 formed over the interfacial layer 238, and a gate electrode layer 242 formed over the high-k dielectric layer 244. Portions of the gate stacks 240 and surrounding features are enlarged in FIGS. 3A-3B to show details of the layers of the gate stacks 240. The interfacial layer 238 may include silicon dioxide, silicon oxynitride, or other suitable materials. The interfacial layer 238 may be formed by chemical oxidation, thermal oxidation, atomic layer deposition (ALD), chemical vapor deposition (CVD), and/or other suitable methods. The high-k dielectric layer 244 may include a high-k dielectric material such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k ˜3.9). The high-k dielectric layer 244 may be formed by ALD, CVD, metal-organic CVD (MOCVD), PVD, thermal oxidation, and/or other suitable methods. In some embodiments, the gate electrode layer 242 includes a work function layer 246 that is an n-type or a p-type work function layer and a metal fill layer 236 over the work function layer 246. For example, an n-type work function layer may comprise a metal with sufficiently low effective work function, and a p-type work function layer may comprise a metal with a sufficiently large effective work function. For example, an n-type work function layer may include Ta, titanium aluminum (TiAl), titanium aluminum carbide (TiAlC), titanium aluminum oxide (TiAlO), TiAlN, or combinations thereof. For example, a p-type work function layer may include TiN, TaN, WN, or combinations thereof. In some embodiments, the work function layer 246 may include a multi-layer structure, such as a first work function layer 246a and a second work function layer 246b (not depicted). For example, the first work function layer 246a may comprise a metal such as titanium, aluminum, tantalum carbide, tantalum carbide nitride, tantalum silicon nitride, or combinations thereof, and the second work function layer 246b may comprise a metal such as titanium nitride, tantalum nitride, ruthenium, molybdenum, tungsten, platinum, or combinations thereof. In embodiments, the metal fill layer 236 includes aluminum, tungsten, cobalt, copper, and/or other suitable materials. In some embodiments, the metal fill layer 236 disposed over p-type work function layer (also referred to as metal fill layer 236p) is a p-type metal fill layer. In some embodiments, the metal fill layer 236 disposed over n-type work function layer (also referred to as metal fill layer 236n) is an n-type metal fill layer. In some other embodiments, the metal fill layer 236p and 236n disposed over the p-type work function layer and the n-type work function layer is of the same material. The gate electrode layer 242 may be formed by CVD, PVD, plating, and/or other suitable processes. Since the gate stacks 240 include a high-k dielectric layer and metal layer(s), it is also referred to as high-k metal gates.

In some embodiments, the gate stacks 240 are formed after other components of the workpiece 200 (e.g., the source/drain features 214) are fabricated. Such process is generally referred to as a gate replacement process, which includes forming dummy gate structures (not depicted) as a placeholder for the gate stacks 240, forming the source/drain features 214, forming dielectric structures 262 (to be described below) over the dummy gate structures and the source/drain features 214, planarizing the dielectric structure 228 by, for example, CMP, to expose top surfaces of the dummy gate structures, removing the dummy gate structures in the dielectric structure 262 to form trenches that expose the channel regions of the active regions 212, removing the sacrificial layers for channel release, and forming the gate stacks 240 in the trenches and around the channel layers 208 to complete the gate replacement process. Although not shown, in some embodiments, the gate stacks 240 may be partially recessed, and a dielectric cap layer may be formed on the recessed gate stacks 240.

In embodiments, the workpiece 200 further includes gate spacers 252 (shown in FIG. 3A) disposed on sidewalls of the gate stacks 240. The gate spacers 252 may include a dielectric material, such as an oxygen-containing material (e.g., silicon oxide, silicon oxycarbide, aluminum oxide, aluminum oxynitride, hafnium oxide, titanium oxide, zirconium aluminum oxide, zinc oxide, tantalum oxide, lanthanum oxide, yttrium oxide, silicon oxycarbonitride, etc.), a nitrogen-containing material (e.g., tantalum carbonitride, silicon nitride (SiN), zirconium nitride, silicon carbonitride, etc.), a silicon-containing material (e.g., hafnium silicide, silicon, zirconium silicide, etc.), other suitable materials, or combinations thereof. The gate spacers 252 may be a single layered structure or a multi-layered structure. Notably, the composition of the gate spacers 252 is distinct from that of the surrounding dielectric components (e.g., the dielectric structure 262), such that an etching selectivity may exist between the gate spacers 252 and the surrounding dielectric components during subsequent etching processes. In an embodiment, the gate spacers 252 include SiN. The gate spacers 252 may be formed by first depositing a blanket of spacer material over the workpiece 200, and then performing an anisotropic etching process to remove portions of the spacer material to form the gate spacers 252.

In some embodiments, referring to FIG. 3A, the workpiece 200 includes the dielectric structure 262 disposed over the source/drain features 214. The dielectric structure 262 may include a contact etch-stop layer (CESL) 258 and an interlayer dielectric (ILD) layer 256 formed over the CESL 258. The ILD layer 256 includes a dielectric material, such as tetraethylorthosilicate (TEOS), silicon oxide, a low-k dielectric material, doped silicon oxide such as borophosphosilicate glass (BPSG), phosphosilicate glass (PSG), FSG, boron doped silicate glass (BSG), other suitable dielectric materials, or combinations thereof. The ILD layer 256 may include a multi-layer structure having multiple dielectric materials and may be formed by a deposition process such as, for example, CVD, flowable CVD (FCVD), spin-on-glass (SOG), other suitable methods, or combinations thereof. The CESL 258 may comprise silicon nitride, silicon oxynitride, silicon nitride with oxygen or carbon elements, other suitable materials, or combinations thereof, and may be formed by CVD, PVD, ALD, other suitable methods, or combinations thereof. The ILD layer 256 may be deposited after the deposition of the CESL 258.

In some embodiments, referring to FIG. 3B, the workpiece 200 includes a gate isolation structure 216. The gate isolation structure 216 is a dielectric feature that separates one or more long gate stacks into short gate stacks. In an example process, a long gate stack is formed in a first patterning process and then is cut into short gate stacks (e.g., the gate stacks 240) in a second patterning process such that the gate stacks 240 have designed dimensions. The gate isolation structure 216 may be formed by patterning process to form trenches and deposition process to fill in the trenches with one or more dielectric materials. The patterning process includes lithography process and etching process and may use a hard mask to define the regions for the gate isolation structure 216. The etching process may include wet etch, dry etch, or a combination thereof to etch through the conductive materials of the long metal gate structure. The etching process may use one or more etchant. A CMP may be performed after the deposition process to remove the excessive materials of the gate isolation structure 216 deposited on the dielectric structures 262 and the gate stacks 240, and planarize the top surface of the workpiece 200. The gate isolation structure 216 and the isolation feature 218 may collectively provide isolation functions, for example, isolating the gate stack 240a and the gate stack 240c.

As shown in FIGS. 3A and 3B, the workpiece 200 further includes a dielectric structure 266. The dielectric structure 266 is disposed over the fin-cut structures 230, the dielectric structure 262, the gate stacks 240, the gate spacers 252, and the gate isolation structures 216. In some embodiments, the dielectric structure 266 includes multiple dielectric layers 264 and contact etch stop layers (CESLs) 268. The CESLs 268 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The dielectric layers 264 may include tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The dielectric layers 264 may be formed by PECVD (plasma enhanced CVD), FCVD (flowable CVD), or other suitable methods.

In some embodiments, referring to FIGS. 2 and 3A, the workpiece 200 further includes source/drain (S/D) contacts 222 over the source/drain features 214. The S/D contacts 222 may extend through the dielectric structure 262 and a portion of the dielectric structure 266 (e.g., a dielectric layer 264 and a CESL 268). In some embodiments, the workpiece 200 further includes a silicide feature 224 between the source/drain contacts 222 and the source/drain features 214. The silicide feature 224 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In an embodiment, the S/D contacts 222 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), or other metals, and may be formed by CVD, PVD, ALD, plating, or other suitable processes. In some embodiments, the conductive barrier layer is omitted in the S/D contacts 222. Some of the S/D contacts 222 (such as shown in FIG. 2) connect multiple S/D features 214 and are referred to as long contact in some instances.

As shown in FIGS. 2 and 3B, the workpiece 200 further includes gate vias 256 that connect the gate stacks 240 and metal lines 250 (to be described below). The gate vias 256 may be embedded in the dielectric structure 266 as depicted. The gate vias 256 may include similar materials and may be formed similarly as the S/D contacts 222. Referring to FIG. 2, the workpiece 200 includes source/drain vias 257. The source/drain vias 257 may be embedded in the dielectric structure 266 and connect the source/drain contacts 222 and metal lines 250 and/or VDD (to be described below). The source/drain vias 257 may include similar materials and may be formed similarly as the gate vias 256.

In some embodiments, the workpiece 200 further includes conductive features embedded in the dielectric structure 266. In some embodiments, the dielectric structure 266 includes more layers of the dielectric layers 264 and the CESLs 268 disposed over those illustrated in FIGS. 3A and 3B. The conductive features and the dielectric structure 266 may collectively be referred to as a multilayer interconnect structure (MLI). The conductive features may include metal lines, metal vias, etc. The conductive features electrically connect various devices and/or components (e.g., the source/drain regions 214, the gate stacks 240) of the workpiece 200, such that the various devices and/or components can operate as specified by design requirements for the workpiece 200. The MLI may include one or more interconnect layers. In the depicted embodiment, the MLI includes a metal zero interconnect layer (M0 level) (e.g., the layer including metal lines 250, BL, VDD, and BLB). Although not depicted, the MLI may further include a via one interconnect layer (V1 level), a metal one interconnect layer (M1 level), . . . , a via x interconnect layer (Vx level, x is an integer), and a metal x interconnect layer (Mx level). Each of the M0 level, V1 level, M1 level, . . . Vx level, and Mx level may be referred to as a metal level. Metal lines formed at the M0 level may be referred to as M0 metal lines. Similarly, via or metal lines formed at the V1 level, M1 level, . . . Vx level, and Mx level may be referred to as V1 vias, M1 metal lines, . . . Vx vias, and Mx metal lines, respectively. The present disclosure contemplates MLI having more or less interconnect layers and/or levels, for example, a total number of N interconnect layers (levels) of the MLI with N as an integer ranging from 1 to 10. Each level of the MLI includes conductive features (e.g., metal lines, metal vias) disposed in one or more dielectric layers (e.g., the dielectric layer 264) and CESL (e.g., the CESL 268). In some embodiments, conductive features at a same level of the MLI, such as M0 level, are formed simultaneously. In some embodiments, conductive features at a same level of the MLI have top surfaces that are substantially planar with one another and/or bottom surfaces that are substantially planar with one another.

In embodiments, the V1 level includes V1 vias disposed in the dielectric structure 266, where V1 vias connect M0 metal lines to M1 metal lines. M1 level includes M1 metal lines disposed in the dielectric structure 266. Vx level includes Vx vias disposed in the dielectric structure 266, where Vx vias connect M(x-1) metal lines to Mx metal lines.

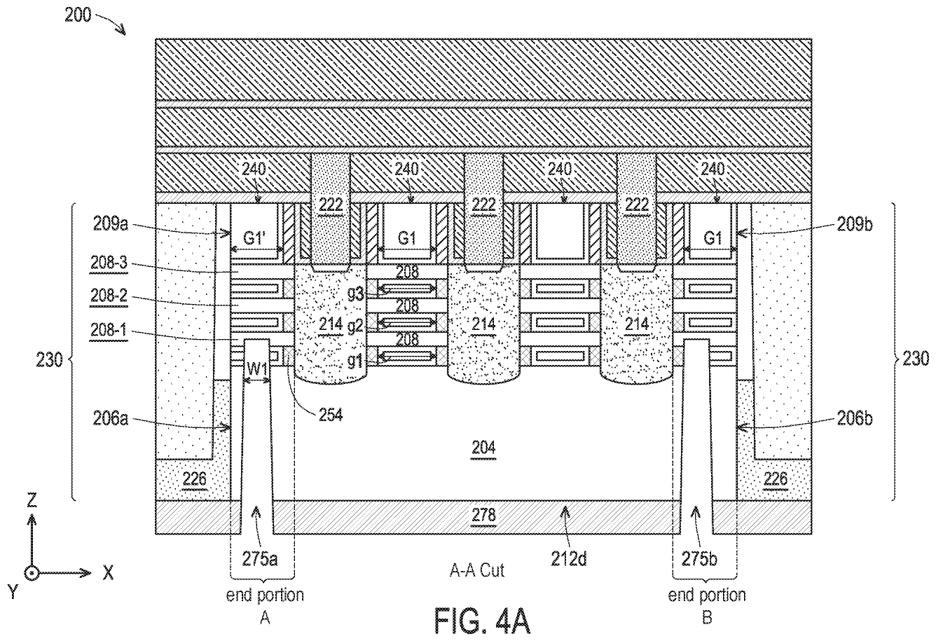

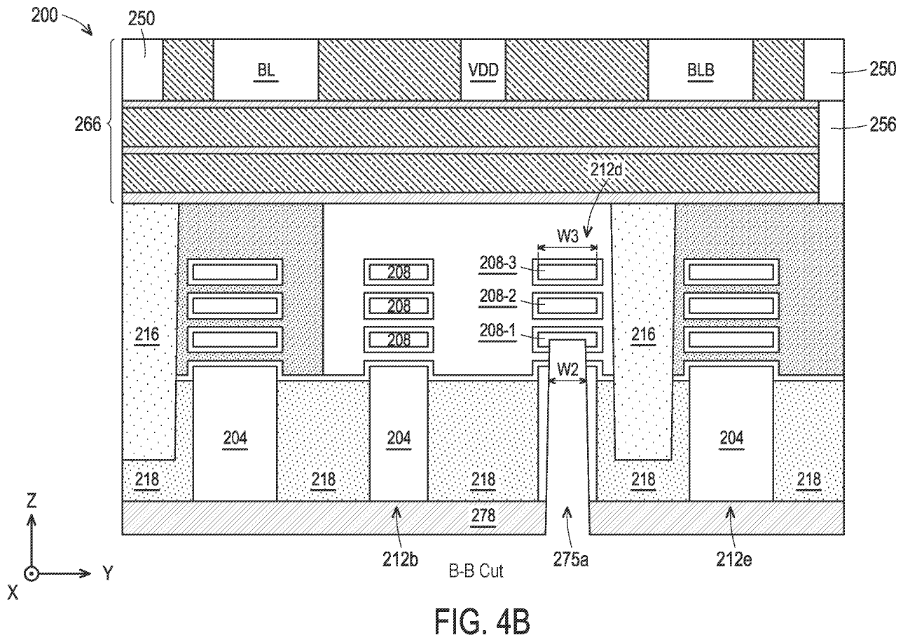

Referring to FIGS. 1, 2, and 4A-4B, method 10 includes a block 14 where trenches 275 are formed from a back side of the substrate 202. FIGS. 4A and 4B illustrate fragmentary cross-sectional views of the workpiece 200 at block 14 along line A-A and line B-B of FIG. 2, respectively. Positions of the trenches 275 (e.g., the trenches 275a, 275b, 275c, and 275d, individually or collectively referred to as the trench(s) 275 dependent upon the context) are illustrated in dashed squares of FIG. 2.

Block 14 may include thinning down the workpiece 200 from the back side of the workpiece 200. In some embodiments, upon completion of the thinning down, the semiconductor bases 204, the first dielectric layer 226, and the isolation feature 218 are exposed from the back side of the workpiece 200. The thinning process may include a mechanical grinding process and/or a chemical thinning process. A substantial amount of substrate material may be first removed from the substrate 202 during a mechanical grinding process. Afterwards, a chemical thinning process may apply an etching chemical to the backside of the substrate 202 to further thin down the substrate 202.

Block 14 may further include forming an etch stop layer 278 over the back side of the workpiece 200. The etch stop layer 278 may comprise silicon nitride, silicon carbon nitride, silicon carbon oxide, carbon nitride, the like, or a combination thereof. A thickness of the etch stop layer 278 may range from about 5 nm to about 15 nm.

In some embodiments, block 14 includes forming the trenches 275. Forming the trenches 275 may include forming a hard mask layer (not shown) below the etch stop layer 278 and performing a lithography patterning and etching process to pattern the hard mask layer. The hard mask layer may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable materials. The patterning of the hard mask layer forms openings directly below certain intersections (as in the dashed squares in FIG. 2) of the gate stacks 240 and the active regions 212. As in the depicted embodiment, the intersections are at end portions of the active regions 212b, 212c, and 212d. As depicted in FIG. 4A, an end portion A or B of the active region 212 may be adjacent to a fin-cut structure 230 and may include a stack of channel layers 208, such that the stack of channel layers 208 is disposed between one adjacent source/drain feature 214 and the fin-cut structure 230. In some embodiments, such as the end portion B, a complete gate stack 240 having a width G1 along the X direction is disposed over the end portion B, and an end 206b of the active region 212 aligns with an end 209b of the gate stack 240. In some embodiments, such as the end portion A, an incomplete gate stack 240 having a width G1′ along the X direction is disposed over the end portion A, and an end 206a of the active region 212 aligns with an end 209a of the gate stack 240. G1′ may be about 0.5 times of G1 to about G1. In some other embodiments not depicted, the end 206b is beyond the end 209b by equal to or less than G1 along the X direction. For ease of description, the channel layers 208 at the intersections are labeled as 208-1, 208-2, and 208-3 from bottom to top. It is noted that the channel layers 208 at the end portions of the active regions 212b, 212c, and 212d are not parts of the transistors (e.g., pull-up transistors PU-1, PU-2, pull-down transistors PD-1, PD-2, pass-gate transistors PG-1, PG-2) of the workpiece 200. Thus, forming the trenches 275 and the subsequent processes at the end portions does not damage the functional channel layers 208 of the transistors. Then, one or more etching processes are performed using the hard mask layer as a mask to form the trenches 275. The one or more etching processes may include multiple steps and involve various etching fluids. The one or more etching processes may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant.

The trenches 275 may extend through the etch stop layer 278 and the semiconductor base 204. In embodiments, each of the trenches 275 extends to contact a channel layer 208 (e.g., the channel layer 208-1). In embodiments, the trenches 275 expose a bottom surface of the channel layer 208. In some embodiments, the trenches 275 extend into the channel layer 208 (e.g., the channel layer 208-1) and further expose sidewall surfaces of the channel layer 208. In the depicted embodiment, the channel layer 208 is a bottommost channel layer 208-1. A portion of the gate stacks 240 below the channel layer 208 is also extended through by the trench 275. In some embodiments (e.g., the trench 275a), the trench 275 is spaced apart from the inner spacer 254 and the fin-cut structure 230. In some other embodiments (e.g., the trench 275b), the trench 275 exposes the inner spacer 254 and/or the fin-cut structure 230. The trench 275 does not expose or extend into the adjacent source/drain feature 214. In other words, during the forming of the trench 275, damage to the source/drain feature 214 is avoided, which may bring benefits to the operation of the workpiece 200.

Referring to FIG. 4A, in some embodiments, the trench 275 has a width W1 along the X direction. The gate stacks 240 each include an upper portion over the stack of the channel layers 208 and inner layers interleaving with the channel layers 208. The upper portion has the width G1 along the X direction, and the lower layers each have a width (e.g., g1, g2, g3) along the X direction. In embodiments, a ratio (e.g., W1/G1) of W1 to G1 is about 0.5 to about 1. A ratio (e.g., W1/g1, W1/g2, W1/g3) of W1 to a width of an inner layer is about 0.5 to about 1. These ranges are not arbitrary. If one of the ratios is greater than about 1, a portion of the inner spacers 254 adjacent to the trench 275 may be removed during the forming of the trench 275, thus isolation provided by the inner spacers 254 is reduced, which may cause electrical short between the adjacent source/drain feature 214 and the backside buried contact to be formed in the trench 275. If one of the ratios is less than about 0.5, resistance of the backside buried contact to be formed in the trench 275 may be too large, causing too much energy waste during operation of the workpiece 200.

Referring to FIG. 4B, in some embodiments, the trench 275 has a width W2 along the Y direction. The channel layers 208 may have a width W3 along the Y direction. In embodiments, a ratio (W2/W3) of W2 to W3 is about 0.5 to about 2. If the ratio is greater than about 2, the trench 275 may extend into the adjacent gate isolation structure 216 and/or may be too close to the adjacent stacks of channel layers 208 of the active region 212b or 212e, and it may unnecessarily increase the footprint of the backside buried contact and the costs associated therewith. If the ratio is less than about 0.5, resistance of the backside buried contact to be formed in the trench 275 may be too large, causing too much energy waste during operation of the workpiece 200.

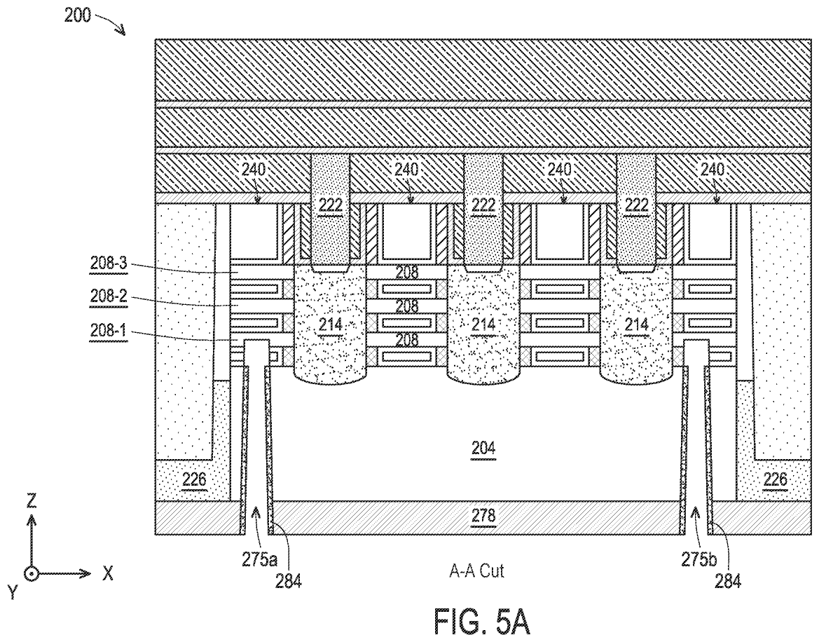

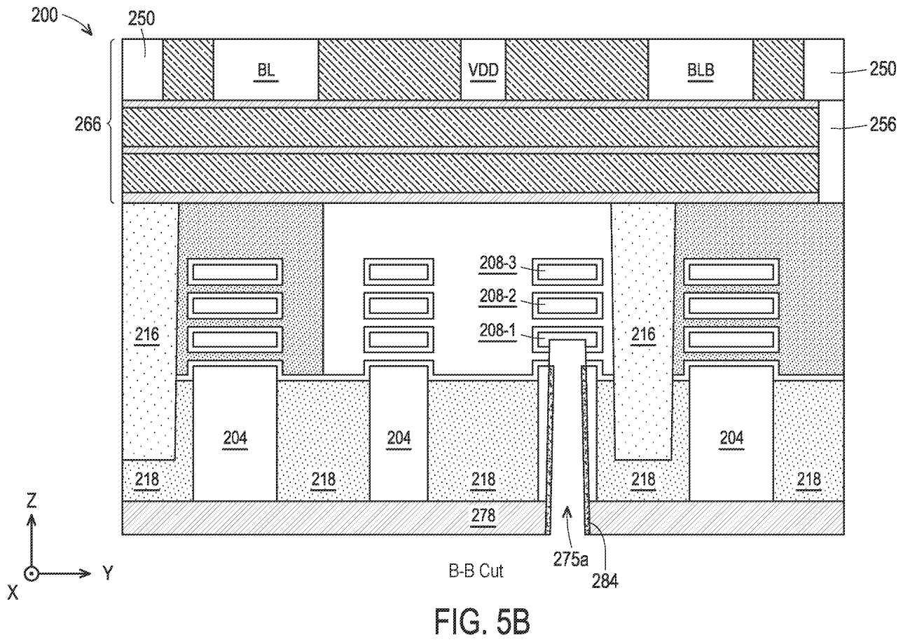

Referring to FIGS. 1 and 5A-5B, method 10 includes a block 16 where a barrier layer 284 is formed on a portion of sidewalls of the trench 275. FIGS. 5A and 5B illustrate fragmentary cross-sectional views of the workpiece 200 at block 16 along line A-A and line B-B of FIG. 2, respectively. This step is optional.

The barrier layer 284 may include a dielectric material such as silicon oxide, silicon nitride, silicon carbide, silicon oxynitride, SiCN films, silicon oxycarbide, SiOCN films, and/or combinations thereof. In some embodiments, the barrier layer 284 includes silicon nitride. By way of example, the barrier layer 284 may be formed by blanket depositing a dielectric material layer in a conformal manner over the back side of the workpiece 200 using processes such as, a CVD process, an SACVD process, an ALD process, a PVD process, or other suitable process. In the illustrated embodiment, the deposition of the dielectric material layer is followed by an etching-back (e.g., anisotropically) process to remove the dielectric material layer from horizontal surface(s) and a top portion of sidewall surface(s) of the trench 275. In some embodiments, the etching-back process may include a wet etch process, a dry etch process, a multiple-step etch process, and/or a combination thereof. In some embodiments, the etching-back process includes a directional etching process (e.g., a tilted plasma etching), in which an ion beam may be directed to a surface of workpiece 200 with a tilt angle with respect to the Z direction. In embodiments, surfaces of the channel layer 208-1 and sidewall surfaces of the inner layer of the gate stack 240 below the channel layer 208-1 are exposed after the etching-back process. The dielectric material layer may remain on sidewalls of the semiconductor base 204 and the etch stop layer 278 as the barrier layer 284. The resultant structure after the etching-back process is shown in FIGS. 5A-5B. The barrier layer 284 provides electrical isolation between the backside metal fill 286 (to be described below) and the semiconductor base 204. In some embodiments, the deposited barrier layer 284 is first treated such that its composition is changed. In this case, the treated portion of the barrier layer 284 remains during the etching-back process and the untreated portion is removed by the etching-back process. In furtherance of the embodiments, the barrier layer 284 includes silicon oxide, and the treating process includes a tilted ion implantation using proper ions, such as nitrogen ions so that nitrogen is introduced into a bottom portion of the barrier layer 284. Thereafter, the treated portion of the barrier layer 284 is selectively removed by the etching-back process using a proper etchant such as phosphorous acid.

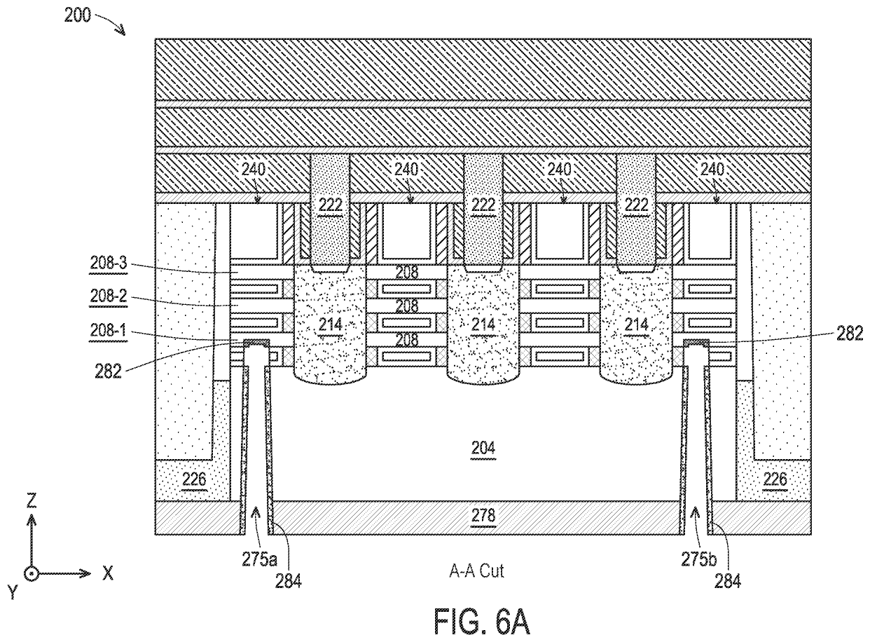

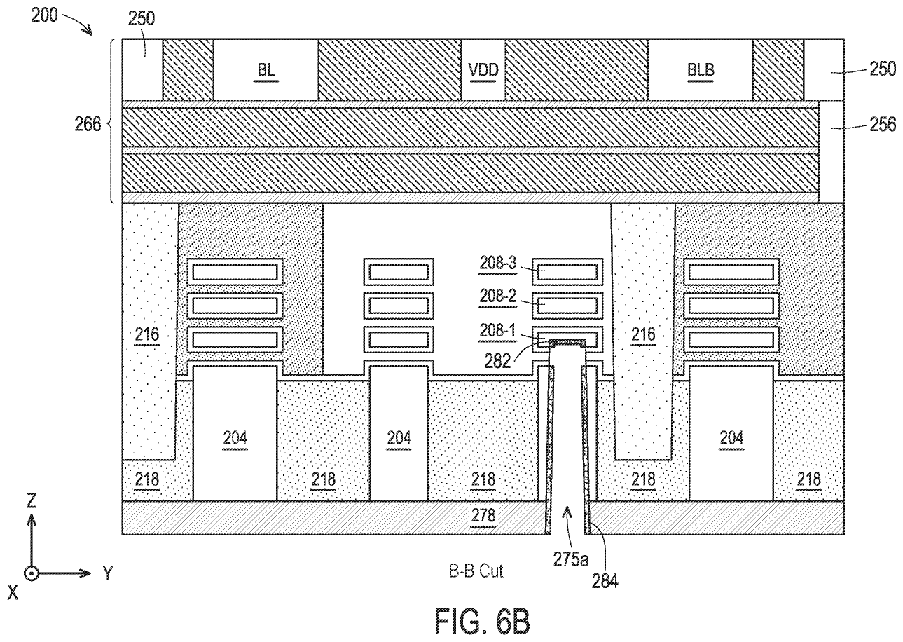

Referring to FIGS. 1 and 6A-6B, method 10 includes a block 18 where a silicide feature 282 is formed on a top portion of surfaces of the trench 275. FIGS. 6A and 6B illustrate fragmentary cross-sectional views of the workpiece 200 at block 18 along line A-A and line B-B of FIG. 2, respectively. This step is optional.

Forming the silicide feature 282 may include depositing one or more metals into the trench 275 using CVD, PVD, ALD, or other suitable methods, performing an annealing process to the workpiece 200 to cause reaction between the one or more metals and the exposed channel layer 208 to produce the silicide feature 282, and removing un-reacted portions of the one or more metals, leaving the silicide feature 282 in the trench 275. In such embodiments, the silicide feature 282 is formed on exposed surface(s) (e.g., the exposed bottom surface and the exposed sidewall surfaces) of the channel layer 208, but not on exposed sidewall surfaces of the inner layer of the gate stack 240. In the depicted embodiment, the silicide feature 282 is formed on a top surface and a top portion of sidewalls of the trench 275. In the depicted embodiments, the silicide feature 282 is continuous. The silicide feature 282 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. In some embodiments, the silicide feature 282 includes TiSi. The silicide feature 282 is formed between the channel layer 208 and the backside metal fill 286 (to be described below) to further reduce contact resistance.

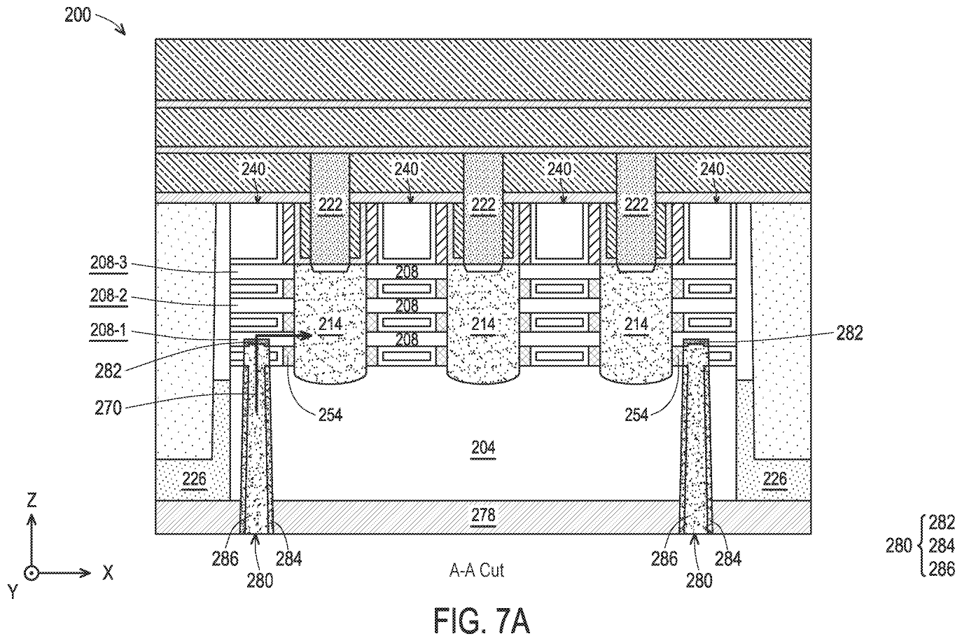

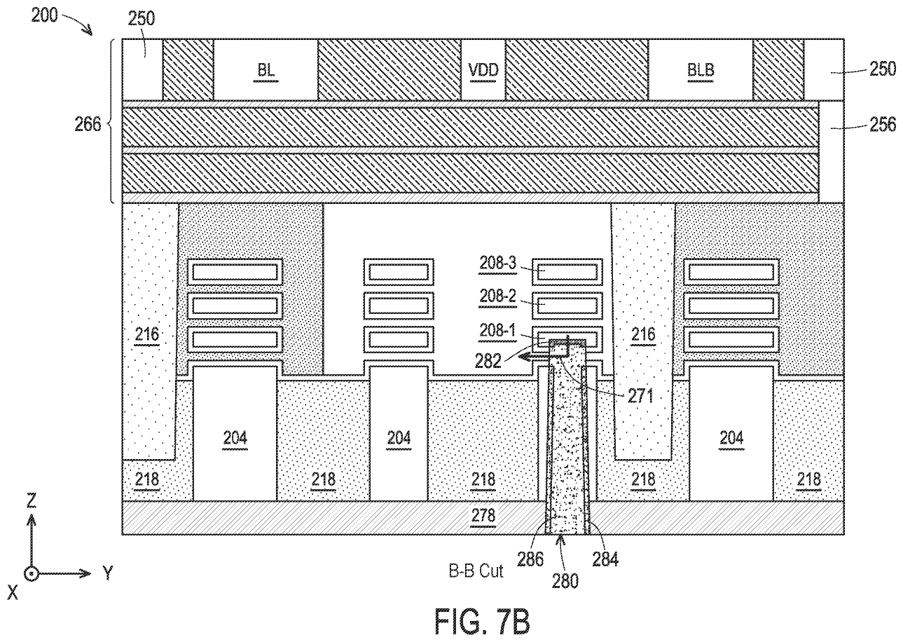

Referring to FIGS. 1 and 7A-7B, method 10 includes a block 20 where a backside metal fill 286 is formed in the trench 275. FIGS. 7A and 7B illustrate fragmentary cross-sectional views of the workpiece 200 at block 20 along line A-A and line B-B of FIG. 2, respectively.

The backside metal fill 286 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the backside metal fill 286 includes W. A planarization operation, such as a CMP process, is performed to remove excessive conductive material of the backside metal fill 286. The etch stop layer 278 may function as a stop layer for the planarization operation, such that the planarization operation also removes the hard mask layer.

The resultant structure after the planarization operation is shown in FIGS. 7A-7B. The silicide feature 282, the barrier layer 284, and the backside metal fill 286 collectively form the backside buried contact 280. The backside buried contact 280 substantially tracks the shape and dimension of the trench 275. In embodiments, the backside buried contact 280 is electrically connected to the channel layer 208 (e.g., the channel layer 208-1), which is connected to the adjacent source/drain feature 214. Thus, the backside buried contact 280 is electrically connected to the adjacent source/drain feature 214 by the channel layer 208-1, a conductive path of which is shown as an arrow 270 in FIG. 7A. In the depicted embodiment, the backside metal fill 286 directly contacts sidewalls of the inner layer of the gate stack 240. Thus, the backside buried contact 280 is electrically connected to the gate stack 240. A conductive path between the gate stack 240 and the channel layer 208-1 is shown as an arrow 271 in FIG. 7B. Thus, the gate stack 240 and the adjacent source/drain feature 214 are electrically connected by the backside buried contact 280 and the channel layer 208. In some embodiments, the backside buried contact 280 functions as a local interconnect feature and is not connected to a backside metal line or a backside via. The backside metal fill 286 may be spaced apart from the adjacent source/drain feature by at least the inner spacer 254. In embodiments, the backside buried contact 280 directly contacts the inner spacer 254 and/or the fin-cut structure 230.

In some embodiments, referring back to FIG. 2, the metal lines BL, VDD, BLB extend lengthwise in the X direction and are spaced apart along the Y direction. A spacing between the metal lines BL and VDD may be the same as a spacing between the metal lines VDD and BLB. Because the backside buried contacts 280 are disposed below the transistors, and no frontside butted contacts are needed for connecting gate stacks 240 and adjacent source/drain features 214, available space in the M0 level is increased. Thus, the M0 metal lines BL, VDD, BLB may have increased widths along the Y direction. In some embodiments, the metal line VDD has a rectangle shape from a top view as in FIG. 2 and has an increased width along the Y direction to reduce resistance. In embodiments, widths of the metal lines BL, VDD, BLB along the Y direction are D1, D2, and D3, respectively. A ratio of D2/D1 is about 0.5 to about 2. A ratio of D2/D3 is about 0.5 to about 2. If the ratio of D2/D1 or the ratio of D2/D3 is greater than about 2, the metal line VDD may be too close to the adjacent metal line BL or metal line BLB, thus isolation therebetween may be too small. If the ratio is less than about 0.5, resistance of the metal line VDD may be too large, causing too much voltage drop and/or energy waste during operation of the workpiece 200.

FIG. 8 is a circuit diagram of an exemplary SRAM cell 300, which is equivalent to the portion 300 of the workpiece 200 in the dashed rectangle on the left in FIG. 2. The SRAM cell 300 can be implemented as a memory cell of a SRAM array (e.g., 1×2 SRAM array in FIG. 2), according to various aspects of the present disclosure. In the illustrated embodiment, the SRAM cell 300 is a single-port (SP) six-transistor (6T) SRAM cell. In various embodiments, the SRAM cell 300 may be other types of memory cells, such as dual-port memory cell or a memory cell having more than six transistors. FIG. 8 has been simplified for the sake of clarity to better understand the inventive concepts of the present disclosure. Additional features can be added in single-port SRAM cell 300, and some of the features described below can be replaced, modified, or eliminated in other embodiments of single-port SRAM cell 300.

The exemplary SRAM cell 300 includes six transistors: the pass-gate transistor PG-1, the pass-gate transistor PG-2, the pull-up transistor PU-1, the pull-up transistor PU-2, the pull-down transistor PD-1, and the pull-down transistor PD-2. In operation, the pass-gate transistor PG-1 and the pass-gate transistor PG-2 provide access to a storage portion of the SRAM cell 300, which includes a cross-coupled pair of inverters, an inverter 392 and an inverter 394. The inverter 392 includes the pull-up transistor PU-1 and the pull-down transistor PD-1, and the inverter 394 includes the pull-up transistor PU-2 and the pull-down transistor PD-2. The pull-up transistors PU-1, PU-2 are configured as p-type GAA transistors, and the pull-down transistors PD-1, PD-2 are configured as n-type GAA transistors as described above.

A gate of the pull-up transistor PU-1 interposes a source (electrically coupled with a power supply voltage (V_{DD})) and a first common drain (CD1), and a gate of pull-down transistor PD-1 interposes a source (electrically coupled with a power supply voltage (V_{SS}), which may be an electric ground) and the first common drain. A gate of pull-up transistor PU-2 interposes a source (electrically coupled with the power supply voltage (V_{DD})) and a second common drain (CD2), and a gate of pull-down transistor PD-2 interposes a source (electrically coupled with the power supply voltage (V_{SS})) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2) by the backside buried contact 280 (e.g., the backside buried contact 280 in FIG. 7A, which is formed in the trench 275a in FIG. 2). The gate of the pull-up transistor PU-2 and the gate of the pull-down transistor PD-2 are coupled with the first common drain (CD1) by another backside buried contact 280 (e.g., the backside buried contact 280 formed in the trench 275c in FIG. 2). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

A gate of the pass-gate transistor PG-1 is formed from the gate stack 240b, a gate of the pull-down transistor PD-1 is formed from the gate stack 240a, a gate of the pull-up transistor PU-1 is formed from the gate stack 240a, a gate of the pull-up transistor PU-2 is formed from the gate stack 240d, a gate of the pull-down transistor PD-2 is formed from the gate stack 240d, and a gate of the pass-gate transistor PG-2 is formed from the gate stack 240c. The bit lines BL and BLB may include the metal lines BL and BLB in FIG. 7B, respectively. The power supply voltage (V_{DD}) may be provided through the metal line VDD in FIG. 7B.

FIGS. 9A-9B illustrate fragmentary cross-sectional views of an alternative workpiece 400 along line A-A and line B-B of FIG. 2, respectively. A difference of the workpiece 400 from the workpiece 200 includes that the silicide feature 282 is formed by depositing a silicide layer in the trenches 275. In some embodiments, the silicide layer is deposited conformally in the trenches 275 and bottom surfaces of the etch stop layer 278 during operations in block 18. In such embodiments, the operations in block 18 further include performing an etching-back process to remove the silicide layer from a bottom portion of the sidewalls of the trenches 275 and the bottom surfaces of the etch stop layer 278. Remaining portion of the silicide layer forms the silicide feature 282 over sidewall surfaces of the inner layer of the gate stack 240 and surfaces of the channel layer 208-1 as depicted in FIGS. 9A-9B. In some embodiments, the silicide feature 282 is disposed between the backside metal fill 286 and the channel layer 208-1 and the inner layer of the gate stack 240. The silicide feature 282 may include similar materials as the silicide feature 282 of the workpiece 200 in FIGS. 7A-7B.

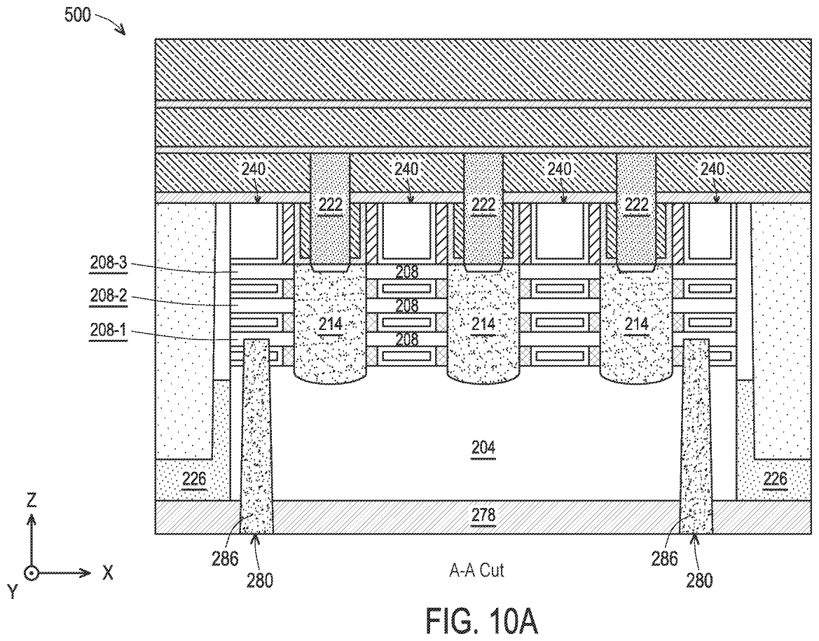

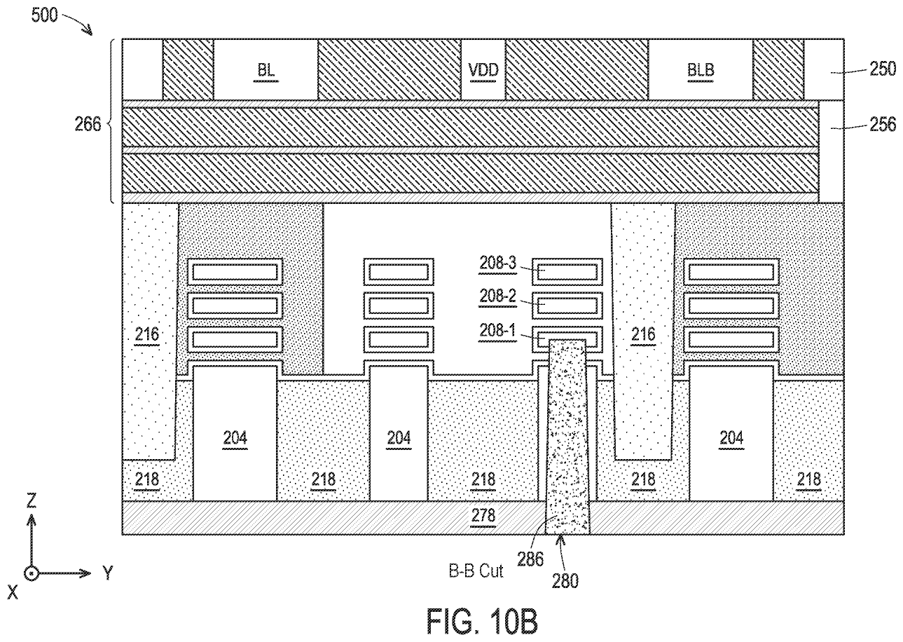

FIGS. 10A-10B illustrate fragmentary cross-sectional views of an alternative workpiece 500 along line A-A and line B-B of FIG. 2, respectively. A difference of the workpiece 500 from the workpiece 200 includes that no silicide feature 282 or barrier layer 284 is formed. In such embodiments, blocks 16 and 18 are both omitted. In the depicted embodiment, the backside metal fill 286 directly contacts the channel layer 208-1, the inner layer of the gate stack 240, the semiconductor base 204, and the etch stop layer 278. In embodiments, the backside metal fill 286 directly contacts the inner spacer 254 and/or the fin-cut structure 230. In some other embodiments not depicted, either block 16 or block 18 is omitted. In such embodiments, only one of the silicide feature 282 and the barrier layer 284 is included in the backside buried contact 280.

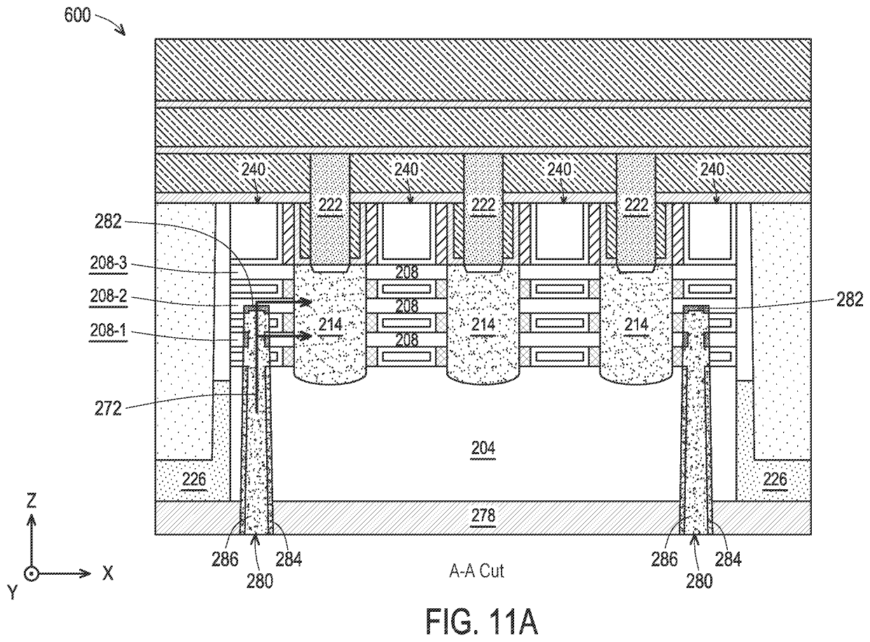

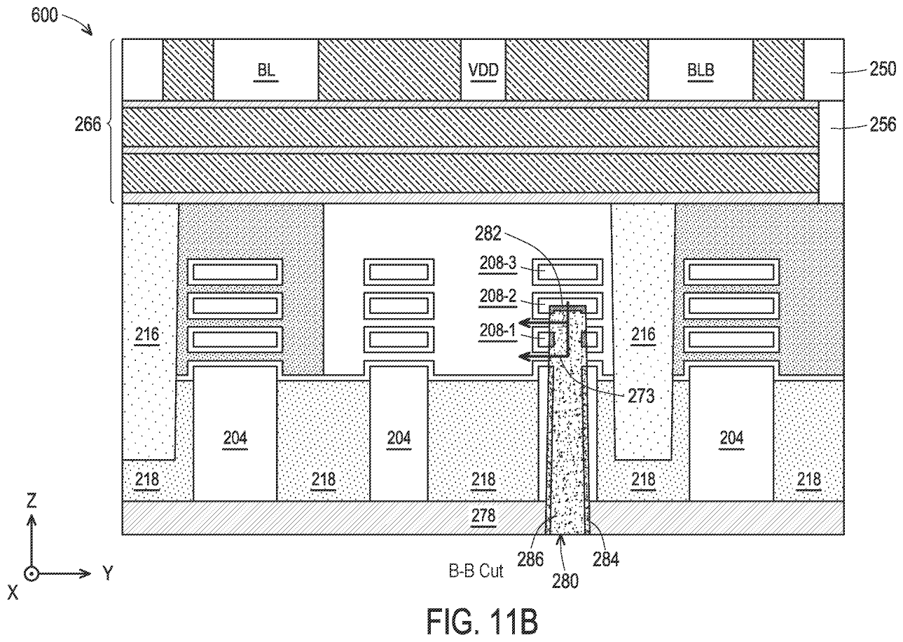

FIGS. 11A-11B illustrate fragmentary cross-sectional views of an alternative workpiece 600 along line A-A and line B-B of FIG. 2, respectively. A difference of the workpiece 600 from the workpiece 200 includes that the backside buried contact 280 extends into the channel layer 208-2. In such embodiments, compared to the workpiece 200, the backside buried contact 280 further extends through the channel layer 208-1 and a second inner layer of the gate stack 240 from the bottom, and extends to contact the channel layer 208-2. In the depicted embodiment, the silicide feature 282 is formed similarly as the silicide feature 282 of the workpiece 200, and is disposed on sidewalls and a bottom surface of the channel layer 208-2 and on sidewalls of the channel layer 208-1. The silicide feature 282 is not disposed on sidewalls of the inner layers of the gate stack 240. Thus, the silicide feature 282 is discontinuous. The arrows 272 illustrate a conductive path between the source/drain feature 214 and the backside buried contact 280. The arrows 273 illustrate a conductive path between the channel layer 208-2 and the gate stack 240. It is understood that the channel layer 208-1 may also be electrically connected to the gate stack 240 by the backside buried contact 280, a conductive path of which is not depicted for ease of reading of the figures.

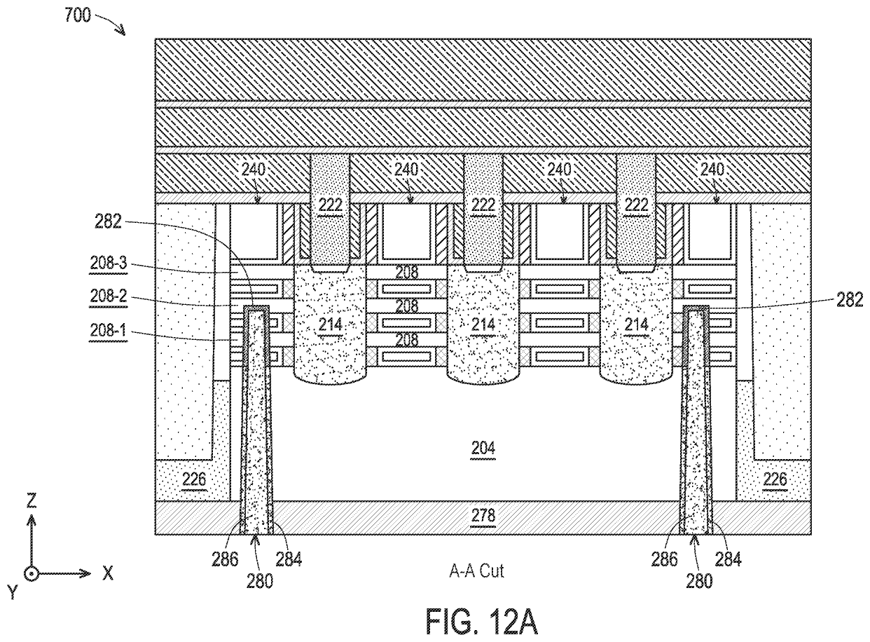

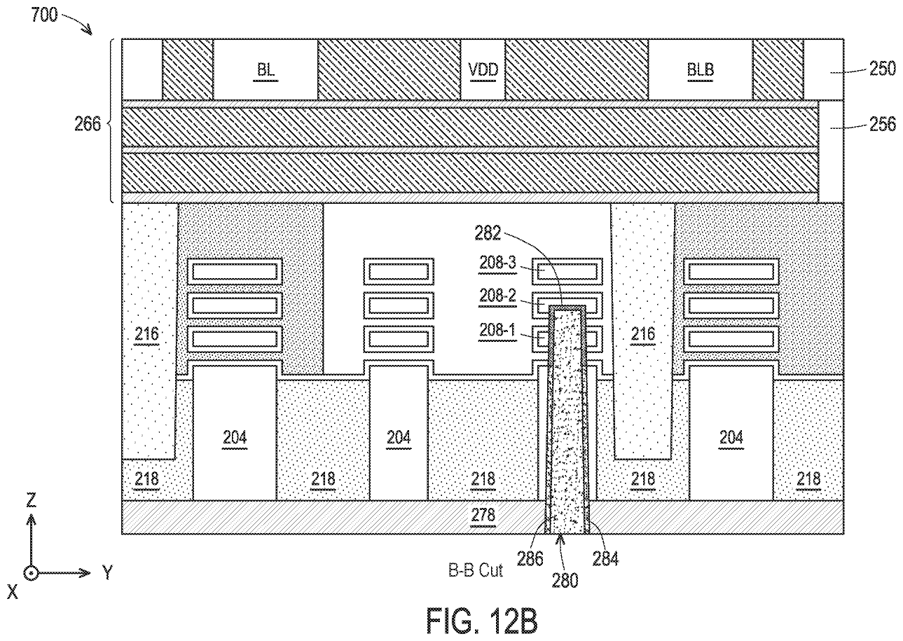

FIGS. 12A-12B illustrate fragmentary cross-sectional views of an alternative workpiece 700 along line A-A and line B-B of FIG. 2, respectively. A difference of the workpiece 700 from the workpiece 600 includes that the silicide feature 282 is formed by depositing a silicide layer in the trenches 275 similar to those described with respect to FIGS. 9A-9B. In such embodiments, the silicide feature 282 is continuous. The silicide feature 282 may be disposed between the backside metal fill 286 and the first and the second inner layer of the gate stack 240 from bottom, and disposed between the backside metal fill 286 and the channel layers 208-1 and 208-2.

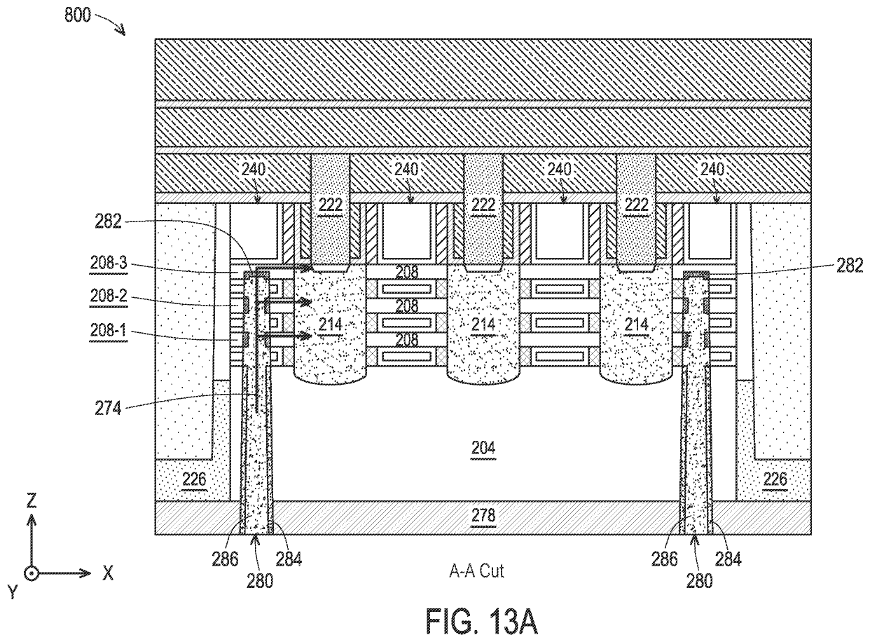

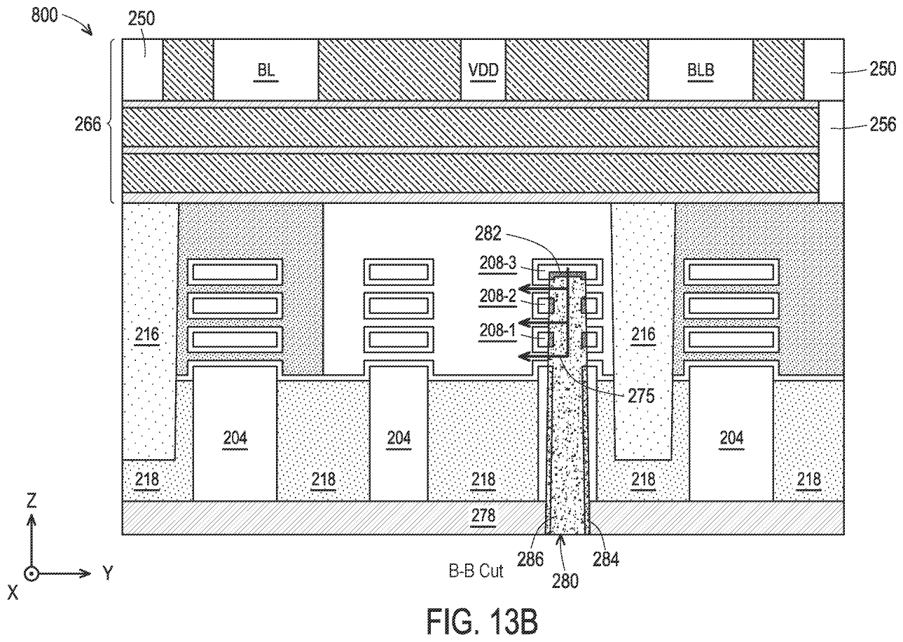

FIGS. 13A-13B illustrate fragmentary cross-sectional views of an alternative workpiece 800 along line A-A and line B-B of FIG. 2, respectively. A difference of the workpiece 800 from the workpiece 600 includes that the backside buried contact 280 extends into the channel layer 208-3. In such embodiments, compared to the workpiece 600, the backside buried contact 280 further extends through the channel layer 208-2 and a third inner layer of the gate stack 240 from the bottom, and extends to contact the channel layer 208-3. In the depicted embodiment, the silicide feature 282 is formed similarly as the silicide feature 282 of the workpiece 600, and is disposed on sidewalls and a bottom surface of the channel layer 208-3 and on sidewalls of the channel layers 208-1 and 208-2. The silicide feature 282 is not disposed on sidewalls of the inner layers of the metal stack 240. Thus, the silicide feature 282 is discontinuous. The arrows 274 illustrate a conductive path between the source/drain feature 214 and the backside buried contact 280. The arrows 275 illustrate a conductive path between the channel layer 208-3 and the gate stack 240. It is understood that the channel layers 208-1 and 208-2 may also be electrically connected to the gate stack 240 by the backside buried contact 280, a conductive path of which is not depicted for ease of reading of the figures.

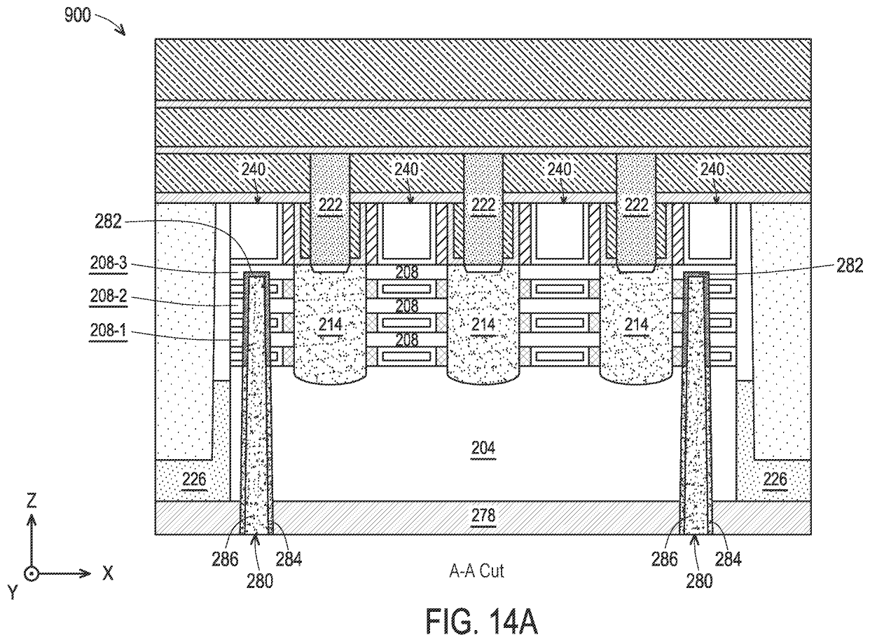

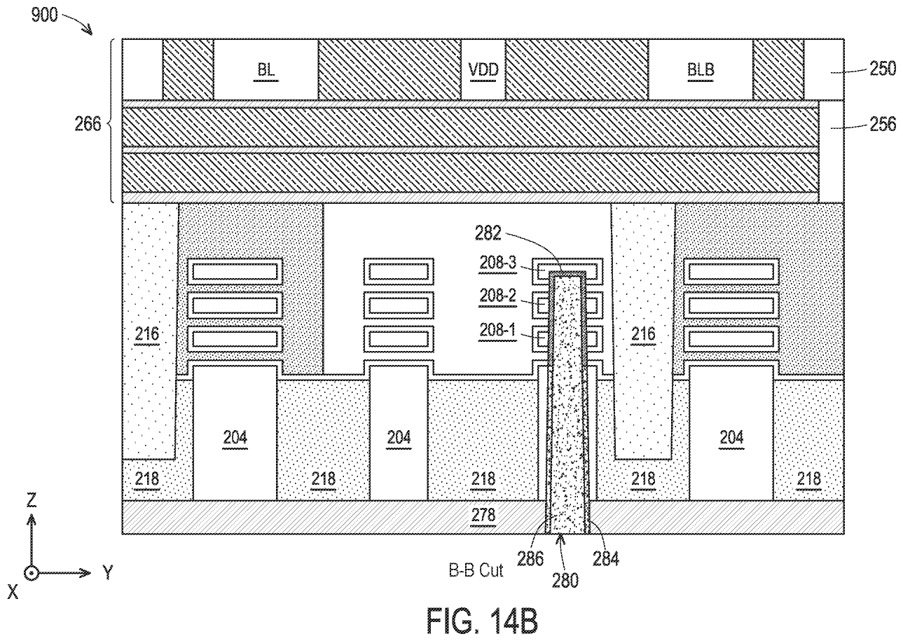

FIGS. 14A-14B illustrate fragmentary cross-sectional views of an alternative workpiece 900 along line A-A and line B-B of FIG. 2, respectively. A difference of the workpiece 900 from the workpiece 800 includes that the silicide feature 282 is formed by depositing a silicide layer in the trenches 275 similar to those described with respect to FIGS. 9A-9B. In such embodiments, the silicide feature 282 is continuous. The silicide feature 282 may be disposed between the backside metal fill 286 and the first, the second, and the third inner layers of the gate stack 240 from bottom, and disposed between the backside metal fill 286 and the channel layers 208-1, 208-2, and 208-3.

It is understood that more channel layers 208 may be included in the stacks of channel layers 208 as described above. The backside buried contact 280 may extend through multiple (e.g., 2, 3, 4, 5, 6, 7, 8, 9, 10) channel layers 208 of the stack.

Although not intended to be limiting, one or more embodiments of the present disclosure provide many benefits to a semiconductor device and the formation thereof. For example, the present disclosure reduces frontside conductive feature density and provides more freedom to the M0 level design by having a backside buried contact. Thus, the M0 metal lines (e.g., the metal line VDD) may have an increased width and a reduced resistance, which may reduce voltage drop and wasted energy during operations of the semiconductor device. The backside buried contact is spaced apart from adjacent source/drain features, thus source/drain feature loss is eliminated, and performance of the semiconductor device may be improved. Further, embodiments of the present disclosure can be readily integrated into existing semiconductor manufacturing processes. For example, the backside buried contact may be formed together with other backside vias (e.g., backside vias below source/drain features) of the semiconductor device.

In one exemplary aspect, the present disclosure is directed to a semiconductor structure. The semiconductor structure includes an active region including a stack of channel layers, a metal gate structure disposed over the stack of channel layers, a source/drain feature disposed over a source/drain region of the active region and adjacent to the stack of channel layers, and a backside via penetrating from a back side of the active region and extending to contact a channel layer of the stack of channel layers. The backside via is electrically connected to the source/drain feature through the channel layer of the stack of channel layers and contacts the metal gate structure.

In some embodiments, the backside via includes a metal fill layer, and a silicide layer disposed between the metal fill layer and the channel layer of the stack of channel layers. In some embodiments, the silicide layer is further disposed between the metal fill layer and the metal gate structure. In some embodiments, the backside via penetrates multiple channel layers of the stack of channel layers, and the silicide layer includes discontinuous segments and is disposed on sidewalls of the multiple channel layers of the stack of channel layers. In some embodiments, the backside via includes a metal fill layer, and a dielectric barrier layer disposed on at least a portion of sidewalls of the metal fill layer. In some embodiments, the channel layer of the stack of channel layers is a bottommost channel layer of the stack of channel layers. In some embodiments, the backside via penetrates multiple channel layers of the stack of channel layers. In some embodiments, the channel layer of the stack of channel layers is a topmost channel layer of the stack of channel layers, and the backside via is electrically connected to each channel layer of the stack of channel layers. In some embodiments, the semiconductor structure further includes an inner spacer disposed between the source/drain feature and the backside via. In some embodiments, the stack of channel layers is disposed in an end portion of the active region.

In another exemplary aspect, the present disclosure is directed to a semiconductor structure. The semiconductor structure includes a fin-like active region including a semiconductor base and a first stack of channel layers and a second stack of channel layers over the semiconductor base, and oriented lengthwise along a first direction and having an end, a first source/drain feature disposed over the semiconductor base of the fin-like active region and between the first stack of channel layers and the second stack of channel layers, a second source/drain feature disposed over the semiconductor base of the fin-like active region and adjacent to the second stack of channel layers, a first metal gate structure disposed over the first stack of channel layers, a second metal gate structure disposed over the second stack of channel layers and wrapping around each channel layer of the second stack of channel layers, and a backside contact feature embedded in the semiconductor base of the fin-like active region, vertically overlapped with the end of the fin-like active region, and in contact with a bottommost channel layer of the first stack of channel layers.

In some embodiments, the backside contact feature includes a silicide layer disposed on sidewalls of the bottommost channel layer of the first stack of channel layers. In some embodiments, the silicide layer has a discontinuous structure with multiple segments contacting and aligned with channel layers of the first stack of channel layers. In some embodiments, the backside contact feature penetrates through a portion of the first metal gate structure below the first stack of channel layers. In some embodiments, the semiconductor structure further includes an inner spacer disposed between the backside contact feature and the first source/drain feature. In some embodiments, the first source/drain feature and the first metal gate structure are electrically connected by the backside contact feature and the bottommost channel layer of the first stack of channel layers.

In yet another exemplary aspect, the present disclosure is directed to a static random-access memory (SRAM) cell. The static random-access memory (SRAM) cell includes a first active region and a second active region extending lengthwise along a first direction, a first metal gate structure disposed over the first active region, a second metal gate structure disposed over the first active region and the second active region, a third metal gate structure disposed over the second active region, a source/drain feature disposed over the first active region and between the first metal gate structure and the second metal gate structure, and a backside via disposed directly under an intersection of the first active region and the first metal gate structure. The first, the second, and the third metal gate structures extend lengthwise along a second direction perpendicular to the first direction. The first active region includes a first stack of channel members and a second stack of channel members connected to the source/drain feature. The second metal gate structure wraps around each channel member of the second stack of channel members. The backside via directly contacts a channel member of the first stack of channel members and the first metal gate structure.

In some embodiments, the backside via is disposed directly under an end portion of the first active region. In some embodiments, the backside via includes a silicide layer disposed on sidewalls of channel members of the first stack of channel members. In some embodiments, the static random-access memory (SRAM) cell further includes a spacer layer disposed between the backside via and the source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an active region including a stack of channel layers;
a metal gate structure disposed over the stack of channel layers;
a source/drain feature disposed over a source/drain region of the active region and adjacent to the stack of channel layers; and
a backside via penetrating from a back side of the active region and extending to contact a channel layer of the stack of channel layers,
wherein the backside via is electrically connected to the source/drain feature through the channel layer of the stack of channel layers and contacts the metal gate structure.

2. The semiconductor structure of claim 1, wherein the backside via includes:
a metal fill layer, and
a silicide layer disposed between the metal fill layer and the channel layer of the stack of channel layers.

3. The semiconductor structure of claim 2, wherein the silicide layer is further disposed between the metal fill layer and the metal gate structure.

4. The semiconductor structure of claim 2,
wherein the backside via penetrates multiple channel layers of the stack of channel layers,
wherein the silicide layer includes discontinuous segments and is disposed on sidewalls of the multiple channel layers of the stack of channel layers.

5. The semiconductor structure of claim 1, wherein the backside via includes:
a metal fill layer, and
a dielectric barrier layer disposed on at least a portion of sidewalls of the metal fill layer.

6. The semiconductor structure of claim 1, wherein the channel layer of the stack of channel layers is a bottommost channel layer of the stack of channel layers.

7. The semiconductor structure of claim 1, wherein the backside via penetrates multiple channel layers of the stack of channel layers.

8. The semiconductor structure of claim 7,
wherein the channel layer of the stack of channel layers is a topmost channel layer of the stack of channel layers, and
wherein the backside via is electrically connected to each channel layer of the stack of channel layers.

9. The semiconductor structure of claim 1, further comprising an inner spacer disposed between the source/drain feature and the backside via.

10. The semiconductor structure of claim 1, wherein the stack of channel layers is disposed in an end portion of the active region.

11. A semiconductor structure, comprising:
a fin-like active region including a semiconductor base and a first stack of channel layers and a second stack of channel layers over the semiconductor base, and oriented lengthwise along a first direction and having an end;
a first source/drain feature disposed over the semiconductor base of the fin-like active region and between the first stack of channel layers and the second stack of channel layers;
a second source/drain feature disposed over the semiconductor base of the fin-like active region and adjacent to the second stack of channel layers;
a first metal gate structure disposed over the first stack of channel layers;
a second metal gate structure disposed over the second stack of channel layers and wrapping around each channel layer of the second stack of channel layers; and
a backside contact feature embedded in the semiconductor base of the fin-like active region, vertically overlapped with the end of the fin-like active region, and in contact with a bottommost channel layer of the first stack of channel layers.

12. The semiconductor structure of claim 11, wherein the backside contact feature includes a silicide layer disposed on sidewalls of the bottommost channel layer of the first stack of channel layers.

13. The semiconductor structure of claim 12, wherein the silicide layer has a discontinuous structure with multiple segments contacting and aligned with channel layers of the first stack of channel layers.

14. The semiconductor structure of claim 11, wherein the backside contact feature penetrates through a portion of the first metal gate structure below the first stack of channel layers.

15. The semiconductor structure of claim 11, further comprising an inner spacer disposed between the backside contact feature and the first source/drain feature.

16. The semiconductor structure of claim 11, wherein the first source/drain feature and the first metal gate structure are electrically connected by the backside contact feature and the bottommost channel layer of the first stack of channel layers.

17. A static random-access memory (SRAM) cell, comprising:
a first active region and a second active region extending lengthwise along a first direction;
a first metal gate structure disposed over the first active region;
a second metal gate structure disposed over the first active region and the second active region;
a third metal gate structure disposed over the second active region;
a source/drain feature disposed over the first active region and between the first metal gate structure and the second metal gate structure; and
a backside via disposed directly under an intersection of the first active region and the first metal gate structure,
wherein the first, the second, and the third metal gate structures extend lengthwise along a second direction perpendicular to the first direction,
wherein the first active region includes a first stack of channel members and a second stack of channel members connected to the source/drain feature,
wherein the second metal gate structure wraps around each channel member of the second stack of channel members, and
wherein the backside via directly contacts a channel member of the first stack of channel members and the first metal gate structure.

18. The SRAM cell of claim 17, wherein the backside via is disposed directly under an end portion of the first active region.

19. The SRAM cell of claim 17, wherein the backside via includes a silicide layer disposed on sidewalls of channel members of the first stack of channel members.

20. The SRAM cell of claim 17, further comprising a spacer layer disposed between the backside via and the source/drain feature.
